(19) United States
(12) Patent Application Publication
(10) Pub. No.: US 2008/0186106 A1
(43) Pub. Date: Aug. 7, 2008

(54) Electrical Multiband Component

(76) Inventors: Block Christian, Stainz (AT); Horst Faulhaber, Framental (AT); Christian Korden, Deutschlandsberg (AT); Andreas Waldherr, Munich (DE)

Correspondence Address: FISH & RICHARDSON PC, P.O. BOX 1022, MINNEAPOLIS, MN, 55440-1022, US

(21) Appl. No.: 11/912,805

(22) PCT Filed: Apr. 25, 2006
(86) PCT No.: PCT/EP06/03824

§ 371 Date: Oct. 26, 2007

(30) Foreign Application Priority Data
Apr. 29, 2005 (DE) 102005020086.9

(51) Int. Cl. H03H 9/00

(52) U.S. Cl. 333/133

(57) ABSTRACT

An electrical multiband component includes at least three signal paths, each for the transmitting signals in a corresponding frequency band. A frequency-separating filter includes an input side and an output side. The input side is electrically connected to an antenna path and the output side is electrically connected to the signal paths. A bandpass filter includes a double mode surface acoustic wave (SAW) filter in at least one of the signal paths.

### TECHNICAL FIELD

This patent application describes an electrical multiband component.

### BACKGROUND

A multiband component with a triplexer is known from US 2003/0124984.

A multiband component with a triplexer and a bandpass surface acoustic wave filter in a GPS path is known from US 2004/0116098.

### SUMMARY

Described herein is an electrical multiband component with which largely interference-free reception is possible in a given frequency band, even during data communication in other frequency bands.

An electrical multiband component is described that comprises at least three signal paths, each for the transmission of signals in a frequency band of its own. The component comprises a diplexer, to which an antenna path is connected on the input side and the signal paths are connected at the output. A bandpass filter, comprising a double mode SAW filter (resonator filter with acoustically coupled transducers), is arranged in at least one of the signal paths.

A DMS filter is a resonator filter with acoustically coupled transducers operating with surface acoustic waves. The DMS filter comprises at least one acoustic track that is delimited by two reflectors and comprises a transducer arrangement with at least three transducers.

The multiband component is characterized by low insertion loss in passbands of the signal paths. The signal path with the DMS filter arranged therein has high isolation—in one embodiment more than −40 dB—from other signal paths.

The DMS filter may be implemented as a SAW chip. In an embodiment, the multiband component comprises a carrier substrate on which the SAW chip is located.

The carrier substrate comprises metallization planes and dielectric layers arranged between them, which may be made from ceramic(s) or a laminate.

Additional elements of the component, e.g., low-pass filters, diplexers or matching networks for matching the output impedance of signal paths, can be integrated in the carrier substrate or mounted on the upper side of the substrate. In particular, the above-mentioned antenna-side diplexer can be integrated into the carrier substrate, at least in part. Integration into the substrate means that circuit elements are designed as conductor tracks in at least one of the metallization planes of the carrier substrate.

The first and second signal may be each a transmit/receive path. The third signal path may be a receive path.

The first signal path may be used for a frequency band with a center frequency of approximately 1 GHz or 900 MHz. The second signal path may be used for a frequency band with a center frequency starting from approximately 1800 MHz.

The multiband component may be used for the separation of different mobile radio paths and for the transmission of data in an additional frequency band. In an embodiment, the first and second frequency bands are mobile radio bands and the third frequency band is a GPS band.

For the center frequency f₁ of the first frequency band, the center frequency f₂ of the second frequency band and the center frequency f₃ of the third frequency band, f₁<f₃<f₂. In one embodiment: f₃≧2f₁ and/or f3<f₂<1.5f₃.

The first frequency band can be, for instance, an AMPS band for a CDMA transmission method (AMPS=Advanced Mobile Phone system, CDMA=Code Division Multiple Access). This corresponds to a frequency band of 824-894 MHz with a center frequency f₁ of 859 MHz. The first signal path is assigned to the first frequency band.

The third frequency band may be assigned to GPS signals. GPS stands for Global Positioning System, with a frequency band of 1574.42-1576.42 MHz and a center frequency f₃ of 1575.42 MHz. The third signal path is assigned to the third frequency band.

The second frequency band is assigned, e.g., to a PCS band (PCS=Personal Communication System) of 1850-1990 MHz with a center frequency f₂ of 1920 MHz. The second signal path is assigned to the second frequency band.

The specified multiband component is not limited, however, to a tri-band design. Additional signal or data communication paths, such as a transmit path for UMTS and/or Bluetooth data can also be provided.

The frequency-separating filter may be constructed exclusively from passive circuit elements such as capacitors and inductors. This has the advantage of low power consumption in a terminal device. At least part of the components, or all the components, of the frequency-separating filter can be integrated into the carrier substrate. It is also possible for at least one component of the frequency-separating filter to be formed as a chip mounted on this substrate.

The chips can have surface-mountable contacts (SMD contacts). The chips can also be constructed as bare-dies, which are electrically connected by bond wires to the carrier substrate. The chips, in particular the SAW chip, can alternatively be mounted on the carrier substrate in a flip-chip arrangement.

It is additionally assumed that the bandpass filter is arranged in the third signal path.

The frequency-separating filter may have a multi-level construction. The frequency-separating filter comprises a first diplexer and a second diplexer in one embodiment. The second and third signal paths are combined into a common path by the second diplexer. The common path and the first signal path are combined into the antenna path by the first diplexer.

The first diplexer comprises a first low-pass filter that may be connected to the first signal path, and a first high-pass filter that may be connected to the common path. The second diplexer comprises a second low-pass filter that may be connected to the third signal path and a second high-pass filter that may be connected to the second signal path.

The bandpass filter can have a stopband, i.e., a particularly high suppression of signals, in the first or second frequency range.

The second high-pass filter can have a transfer function that has a pole at a frequency essentially in the first or the third frequency band.

The double mode SAW filter can comprise one or more acoustic tracks, each with an arrangement of several transducers in a row. Several input transducers may be connected in parallel. Several output transducers connected in parallel are provided. The transducer arrangement comprises at least five transducers in one embodiment, wherein input and output transducers of the respective acoustic track may be arranged alternately. In one embodiment, one input transducer is arranged between every two output transducers. In another embodiment, one output transducer is arranged between two input transducers.

The bandpass filter can further comprise at least one SAW resonator, upstream or downstream of the double mode SAW filter. It is also possible to connect one resonator on the input side and another resonator on the output side. The SAW resonator comprises, for example, a transducer that is arranged between two reflectors.

The SAW resonator can be a series or a parallel resonator. A series resonator is inserted into the signal path and a parallel resonator into a shunt arm between the signal path and ground.

The at least one SAW resonator specified here can also be replaced by at least one ladder-type element or a ladder-type arrangement of SAW resonators, which comprises at least one series resonator and at least one parallel resonator.

The bandpass filter can have a symmetrical output in one embodiment. The DMS filter can be advantageously used as a balun.

A third low-pass filter that suppresses signals of the second and the third frequency bands can be arranged in the first signal path. Its transfer function can have a pole at a frequency lying essentially in the second or third frequency band.

A matching network for matching the output impedance of the second signal path for the predetermined second frequency band can be arranged on the output side of the second high-pass filter. A matching network for matching the output impedance of the third signal path for the predetermined third frequency band can also be arranged on the output side of the bandpass filter.

At least one of the signal paths can be separated by a duplexer or a changeover switch into a receive branch and a transmit branch. The duplexers and the changeover switches may be located on the carrier substrate.

In an advantageous embodiment the frequency-separating filter comprises a bandpass filter with a DMS track arranged in the third signal path and a diplexer for separating signals of the first and the second frequency bands. In this case, the bandpass filter is directly connected to the common antenna path, i.e., without an upstream diplexer. The frequency-separating filter is considered a triplexer in this case.

The multiband component can be realized as a compact, e.g., SMD-mountable chip, which is also referred to below as a front-end module. This chip can comprise the following elements (in each signal path if appropriate) in one component in particular: 1) a duplexer, 2) a power amplifier, a power detector, a directional coupler, at least one changeover switch, e.g., for controlling the amplifier, in the transmission branch of the signal path. The integration of a bandpass filter at the input of the power amplifier is provided. Apart from the above-mentioned components of a transmit path, components of at least one receive path, such as an LNA and/or a bandpass filter, can also be realized in the same module.

The multiband component and advantageous configurations thereof will be described below on the basis of schematic figures not true to scale.

### DESCRIPTION OF THE DRAWINGS

FIG. 1 shows an equivalent circuit diagram of a tri-band element with two diplexers connected in series and a DMS filter;

FIG. 2, the structure of the multiband component in cross section;

FIG. 3, an example of an embodiment of the circuit according to FIG. 1;

FIG. 4, a bandpass filter with a DMS filter;

FIG. 5, transfer functions of signal paths of the multiband component;

FIG. 6, the structure in principle of a front-end module comprising a duplexer and a transmission amplifier arranged in the first signal path; and

FIG. 7, the structure in principle of a front-end module comprising a duplexer and a transmission amplifier in each in each of two signal paths.

### DETAILED DESCRIPTION

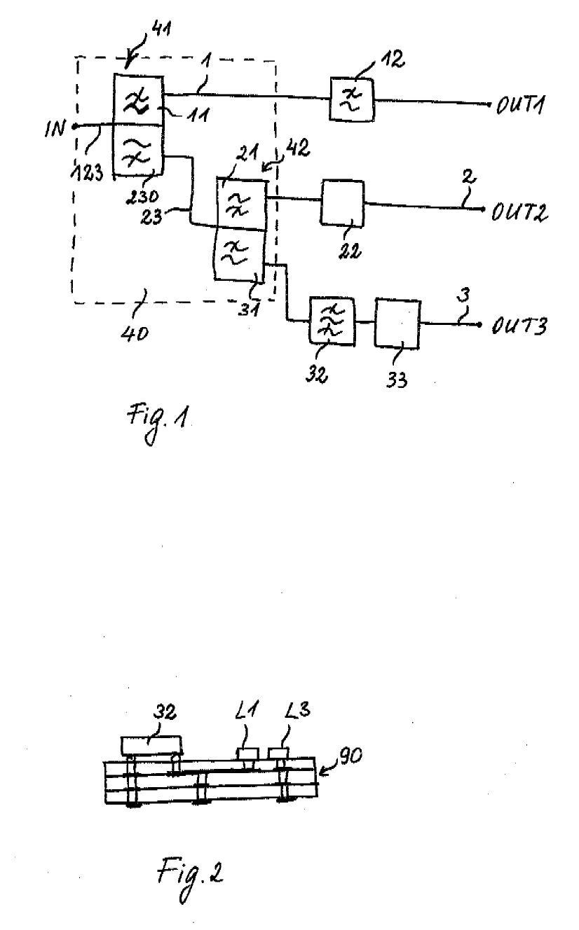

FIG. 1 shows a block diagram of a circuit that is realized in an example of a multiband component. A frequency-separating filter 40 is connected on the input side to an antenna path 123 and thus to an input port IN, which is the antenna input of the component. Frequency-separating filter 40 opens signal paths 1, 2 and 3. First signal path 1 is connected to a first output port OUT1, and second and third signal paths 2, 3 to a respective second and third output port OUT2, OUT3.

Frequency-separating filter 40 comprises diplexers connected in series. Frequency-separating filter 40 comprises a first diplexer 41 connected to the antenna for separating signals of the first frequency band, which are conducted into first signal path 1, from the signals of the second and third frequency bands, which are conducted into a common path 23 for these bands.

A second diplexer 42 is arranged in common path 23. Second diplexer 42 is provided for separating signals of the second frequency band, which are conducted into second signal path 2, from the signals of the third frequency band, which are conducted into third signal path 3.

First diplexer 41 comprises a low-pass filter 11 arranged in the first signal path as well as a high-pass filter 230 arranged in common path 23. Second diplexer 42 comprises a low-pass filter 31 arranged in the third signal path as well as a high-pass filter 21 arranged in second path 2.

In first signal path 1 (e.g., cell), an additional low-pass filter 12 is arranged downstream of low-pass filter 11. In second signal path 2 (e.g., IMT=International Mobile Telecommunications, or PCS), a matching network 22 for matching the output impedance of second output port OUT2 to a reference impedance, e.g., 50Ω, is arranged downstream of high-pass filter 21. Matching network 22 can be integrated into the carrier substrate or be present as a chip mounted on the substrate.

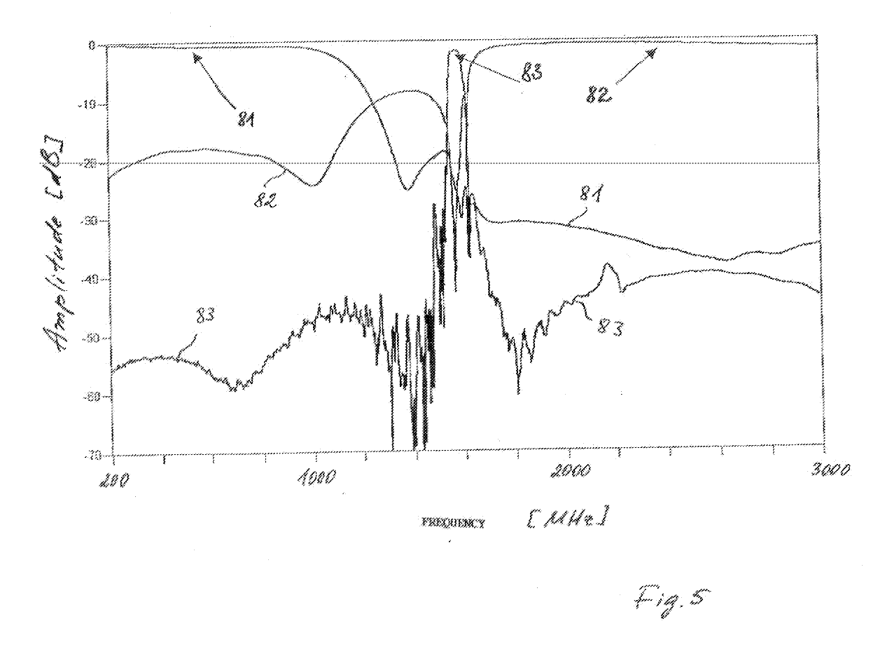

In third signal path 3 (e.g., GPS), a bandpass filter 32 that comprises a DMS filter according to FIG. 4, for example, is arranged downstream of low-pass filter 31. On the output side of third signal path 3, i.e., downstream of bandpass filter 32, a matching network 33 for matching the output impedance of third output port OUT3 is arranged.

It is also possible to arrange a matching network for matching the output impedance of first output port OUT1 on the output side in first signal path 1, i.e., downstream of low-pass filter 12.

The multiband component can comprise components not shown in detail here, in addition to the diplexers, filters and matching networks shown in FIG. 1.

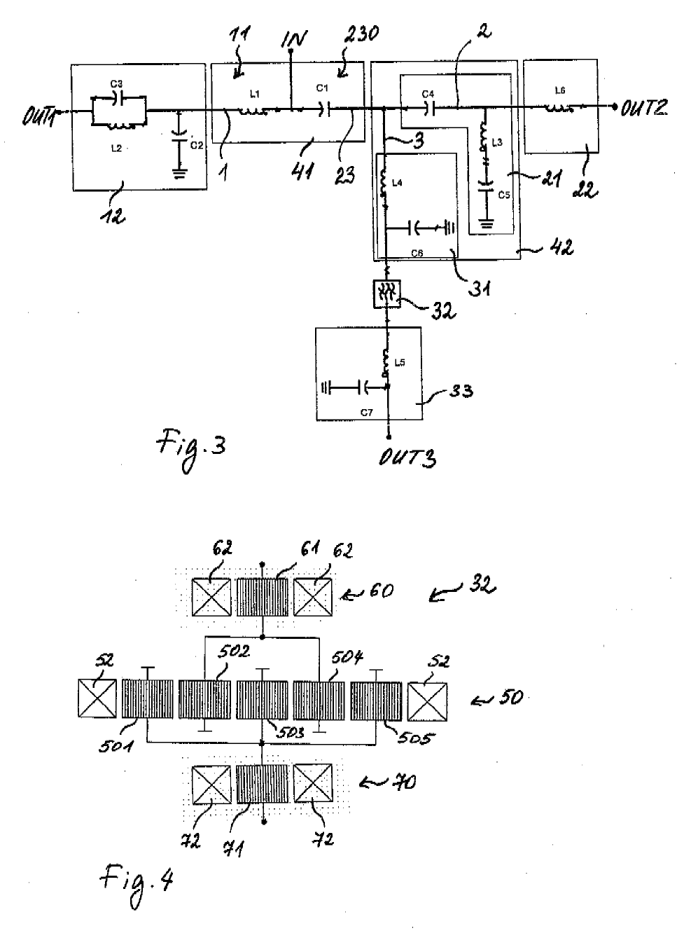

FIG. 2 shows a cross section of the multiband component. The component comprises a carrier substrate 90, which comprises several metallization layers arranged between dielectric layers. Contacts suitable for SMD mounting of the element on a printed-circuit board, not shown here, are provided on the underside of the substrate. On the upper side of the substrate, a bandpass filter 32 realized as a SAW chip, as well as inductors L1 and L3 shown in FIG. 3, formed here as discrete components or chips, are arranged. Inductor L1 is arranged in the low-pass filter of first diplexer 41, and inductor L3 in high-pass filter 21 of second diplexer 42.

In an additional embodiment, it is possible to realize inductors L1 and L3 in at least one metallization plane of carrier substrate 90 as structured, e.g., meander-shaped, folded or spiral conductor tracks. Parts of an inductor can be arranged in different metallization planes and be connected to one another by vertical plated through-holes.

The dielectric layers of the carrier substrate may be made from a ceramic material, e.g., LTCC (LTCC=Low-Temperature Cofired Ceramics). Plastic, e.g., with a high dielectric constant ε>10, is also possible as material for these layers.

The use of a multi-layer substrate as carrier substrate and a surface-mountable SAW chip with the DMS filter has the advantage that a compact element with a small surface area and low insertion loss in passbands of the signal paths can be realized in this manner.

An example of an implementation of the circuit according to FIG. 1 is presented in FIG. 3. Low-pass filter 11 is realized by inductor L1, which transmits the signals of the first band and blocks signals of the other two bands. The high-pass filter 230 is realized by a capacitor C1, which may be arranged in carrier substrate 90. The capacitor transmits the signals of the second and the third bands and blocks the signals of the first band.

Low-pass filter 12 is realized as a capacitor C2 connected to ground in a shunt arm, and a parallel resonant circuit, consisting of an inductor L2 and a capacitor C3, in signal path 1. The low-pass filter 12 selects all signals with a frequency in the first frequency band or below it, and attenuates signals at higher frequencies, in particular, signals from the second and third frequency bands.

High-pass filter 21 comprises a capacitor C4 arranged in signal path 2, and a series resonant circuit, comprised of an inductor L3 and a capacitor C5, connected in a shunt arm to ground. Series resonant circuit L3, C5 may be tuned in such a way that it has its resonant frequency in the third frequency band and thus attenuates the signals of the third band with high suppression. Inductor L3 may have a high Q factor, which can be obtained, e.g., with a chip inductor with SMD contacts.

Low-pass filter 31 comprises a capacitor C6 connected to ground, and an inductor L4 arranged in signal path 3. The low-pass filter 31 transmits signals of the third band and blocks frequencies above the third band. Together with bandpass filter 32, it is possible to select the signals of the third band and attenuate the signals of the first and second bands.

A matching network 33, comprising a series inductor L5 and a capacitor C7 in the shunt arm, which together form a low-pass filter, is inserted downstream of bandpass filter 32. The output impedance at output port OUT3 is matched by matching network 33 to 50Ω, for example, or to some other reference impedance.

Matching network 22 comprises a series inductor L6, which is a part of the multiband component in one embodiment. This inductor can also be arranged externally, i.e., on a printed-circuit board on which the element is mounted. This inductor can also be realized in the carrier substrate. In one embodiment, inductor L6 can serve, for instance, to adapt the output impedance at second output port OUT2 in such a manner that the second signal path 2 can be used for transmission of higher-frequency signals, e.g., signals of the S-DMB-frequency band 2633-2650 MHz (S-DMB=Satellite Digital Multimedia Broadcast). In an embodiment, the second signal path, like the third signal path, can be a pure receive path.

Matching networks 22, 33 can each have circuit components other than inductors L6, L5 and capacitor C7.

The parallel resonance of parallel resonator L2, C3 may be such that this resonant circuit blocks in the second or third frequency band. Thus, a pole or a stopband with a high signal suppression is produced in the transfer function of the first signal path.

The series resonance of the series resonator L3, C5 may be in the first or third frequency band. The signals of this frequency band are short-circuited to ground. A zero or a stopband with high signal suppression is thus produced in the transfer function of the second signal path.

FIG. 4 shows a bandpass filter 32 with a DMS track 50. The DMS track comprises a transducer arrangement, which is situated between acoustic reflectors 52. The transducer arrangement comprises two input transducers 502 and 504 connected in parallel, as well as three output transducers 501, 503 and 505 connected in parallel. The input transducers are acoustically coupled to the output transducers, but galvanically separated from them.

Transducers 504, 504 can also be used as output transducers, in which case transducers 501, 503 and 505 are used as input transducers.

The DMS track can comprise only three transducers or more than only five transducers in one embodiment. The input and output transducers are always alternately arranged in a row in the wave propagation direction. The DMS track may be formed mirror-symmetrically or point-symmetrically relative to its center axis or center point.

At least one transducer, such as a centrally arranged transducer, can have a V-split.

One SAW resonator 60 is connected on the input side of DMS track 50 and another SAW resonator 79 on the output side. Resonator 60 comprises reflectors 62 and a transducer 61 arranged between reflectors 62. Resonator 70 comprises reflectors 72 and a transducer 71 is arranged between reflectors 72.

In one embodiment, at least one of the resonators 60, 70 shown in FIG. 4 can be eliminated.

The use of a DMS track in bandpass filter 32 of third signal path 3 has the advantage that thereby a high isolation—in one embodiment at least −40 dB—of the entire second or third frequency band from the other two frequency bands (i.e., first and the second frequency band) can be ensured.

In the embodiment shown in FIG. 4, the DMS track is connected asymmetrically (unbalanced) on the input and on the output side. In an embodiment, the DMS track can be constructed with a symmetric port (balanced) on the output side.

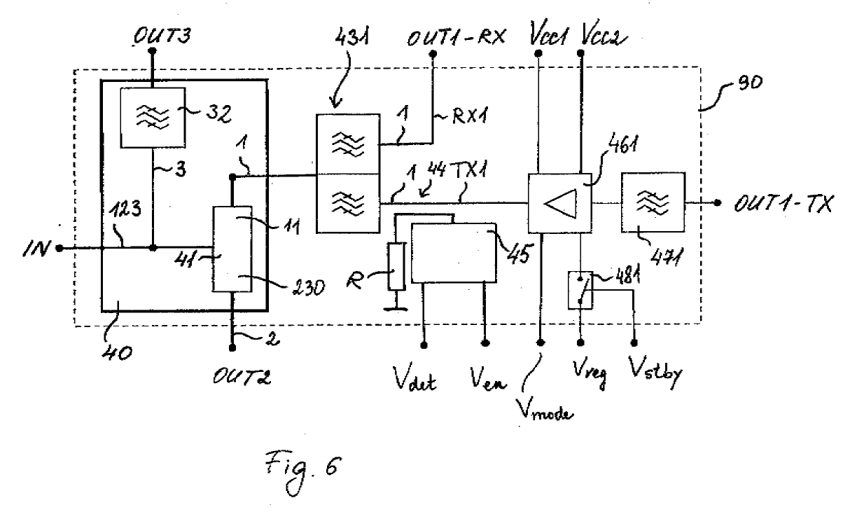

The transfer functions of the multiband component are shown in FIG. 5. Transfer function 81 of the first signal path exhibits low insertion loss even in the low-frequency range below 600 MHz. This has the advantage that signals of a frequency band below 600 MHz can be transmitted via first signal path 1 with low insertion loss. The signals of the first and the additional frequency band can be separated from one another by a diplexer.

Transfer function 82 of the second signal paths exhibits low insertion loss in the frequency range of 1.6 to 3 GHz.

Transfer function 83 of the third signal path has a high suppression of signals in an upper stopband above 1.7 GHz as well as a very high suppression of signals below 1.3 GHz. At the same time low insertion loss in the third frequency band can be obtained in the transfer function of the third signal paths 3.

In one embodiment, additional, e.g., passive components such as duplexers for separating transmit and receive signals of the respective signal paths, can be arranged on or in the carrier substrate. The arrangement of semiconductor chips, e.g., changeover switches, on the substrate can also be contemplated.

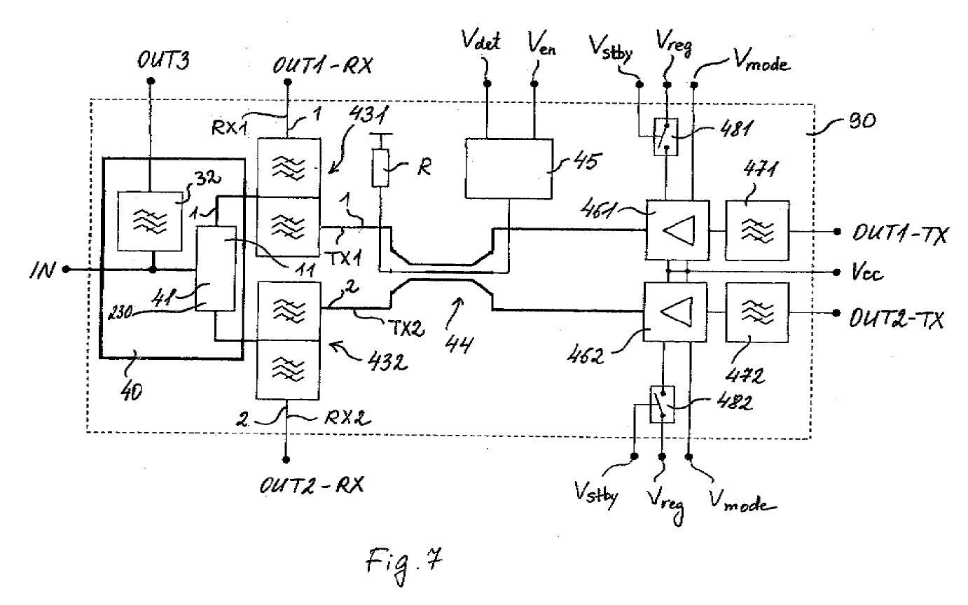

FIGS. 6 and 7 each show an embodiment of the multiband component as a highly integrated front-end module. The broken line represents the carrier substrate 90, on or in which all the components presented in the figures are arranged.

An embodiment of the front-end module which comprises the below-specified components of first signal path 1 is shown in FIG. 6.

Third signal path 3 in FIGS. 6, 7 is directly connected to antenna input IN or antenna path 123. This means that both diplexer 41 and bandpass filter 32 with a DMS track are connected directly to antenna path 123.

Diplexer 41 is provided as in FIG. 1 for separating first and second signal paths 1, 2. A duplexer 431 is arranged in first signal path 1 to separate transmit path TX1 from receive path RX1. Paths RX1 and TX1 are both assigned to the first frequency band. Duplexer 431 comprises two bandpass filters, among them a transmit filter and a receive filter. A power amplifier 461 is arranged in transmit path TX1. A bandpass filter 471, an interstage filter, which may transmit only transmit signals of the first frequency band is arranged at the amplifier input, which corresponds to the output side of the first signal path.

An embodiment of the front-end module, which comprises the below-specified components of the two signal paths 1 and 2 is shown in FIG. 7.

Second signal path 2 is constructed essentially the same as first signal path 1 already described in FIG. 6. A duplexer 432 for separating transmit path TX2 from receive path RX2 is arranged in second signal path 2. Paths RX2 and TX2 are both assigned to the second frequency band. The duplexer 432 comprises two bandpass filters, namely a transmit filter and a receive filter. A power amplifier 462 is arranged in transmit path TX2. A bandpass filter 472, an interstage filter, which may transmit only transmit signals of the second frequency band and, in particular, suppresses the transmit signals of the first frequency band, is arranged at the amplifier input of amplifier 462. This input corresponds to the output side of second signal path 2.

Transmit path TX1 in FIG. 6 is electromagnetically coupled by a directional coupler 44 to an additional signal path, in which a power detector 45 and a terminating resistor R are arranged. In the embodiment shown in FIG. 7, this additional signal path is coupled to both transmit paths TX1, TX2 of signal paths 1 and 2.

Vₑₙ is a supply voltage for supplying the power detector. V_{det} is an output voltage that serves to detect or monitor the signal strength of the amplifier output signal and corresponds to a rectified component of the transmit signal.

Voltages V_{cc}, V_{cc1} and V_{cc2} are supply voltages for the respective amplifier. V_{reg} is a reference voltage for the amplifier. V_{stby} is a control voltage for controlling a changeover switch 481, 482, which is actuated to release reference voltage V_{reg} or set in standby mode. The amplifier does not consume power in standby mode. V_{mode} is a voltage that serves to select and set the operating mode of the amplifier.

In one embodiment, it is possible to integrate components, not shown, of receive paths RX1, RX2 such as a bandpass filter and a low-noise amplifier (LNA) into the specified front-end module.

It is advantageous to realize passive module components such as diplexers, low-pass filters, lines, directional couplers, inductors and capacitors inside the carrier substrate and to realize bandpass filters, duplexers and active components as chips on the carrier substrate.

The components arranged on the carrier substrate, particularly the bandpass filter with the DMS track, can each be constructed as an unpackaged chip (bare-die) or as a housed chip (e.g., an SMD component). A bare-die can be wire-bonded to the carrier substrate or mounted in a flip-chip arrangement.

Duplexers 431, 432 in the embodiments presented in FIGS. 6, 7 are each integrated, at least in part, on carrier substrate 90 or into this substrate.

A duplexer usually comprises a transmit filter, a receive filter and a matching network for impedance matching, comprising, for example, a phase line, such as a λ/4-line, arranged in the receive branch.

It is possible to realize the transmit filter and the receive filter of a duplexer in a common duplexer chip. It is alternatively possible to construct these filters as separate filter chips. The matching network of the duplexer can be integrated, at least in part, into the duplexer chip or filter chip. The λ/4-line may be completely integrated into the duplexer chip. In addition, the matching network of the duplexer can be integrated, at least in part, into the substrate.

The specified multiband component, in particular, the arrangement of matching networks, filters and diplexers, is not limited to the arrangements shown in figures. If appropriate, the diplexer can be constructed in an embodiment as a triplexer, although the arrangement with cascaded diplexers appears particularly advantageous.

What is claimed is:

1. An electrical multiband component comprising:
at least three signal paths each signal path for the transmitting signals in a corresponding frequency band;
a frequency-separating filter having an input side and an output side, the input side being electrically connected to an antenna path and the output side being electrically connected to the signal paths; and
wherein a bandpass filter comprising a double mode surface acoustic wave (SAW) filter in at least one of the signal paths.

2. The electrical multiband component of claim 1, wherein the at least three signal paths comprise:
a first signal path for use in transmitting signals in a first frequency band;
a second signal path for use in transmitting signals in a second frequency band; and
a third signal path for use in transmitting signals in a third frequency band;
wherein the bandpass filter is in the third signal path.

3. The electrical multiband component of claim 2, wherein the frequency-separating filter comprises a first diplexer and a second diplexer;
wherein the second diplexer is configured to interface the second and third signal paths to a common path; and
wherein the first diplexer is configured to interface the common path and first signal path to the antenna path.

4. The electrical multiband component of claim 3, wherein first diplexer comprises a first low-pass filter and a first high-pass filter; and
wherein first high-pass filter interfaces to the common path and the first low-pass filter interfaces to the first signal path.

5. The electrical multiband component of claim 4, wherein the second diplexer comprises a second low-pass filter and a second high-pass filter; and
wherein the second low-pass filter interfaces to the third signal path and second high-pass filter to the second signal path.

6. The electrical multiband component of claim 2, wherein the bandpass filter has a stopband in the second frequency band.

7. The electrical multiband component of claim 2, wherein the bandpass filter has a stopband in the first frequency band.

8. The electrical multiband component of claim 2, wherein, for a center frequency f₁ of the first frequency band, a center frequency f₂ of the second frequency band, and a center frequency f₃ of the third frequency band: f₁<f₃<f₂.

9. The electrical multiband component of claim 8, wherein: f₃≧2f₁.

10. The electrical multiband component of claim 8, wherein: f₃<f₂<1.5f₃.

11. The electrical multiband component of claim 2, wherein the first and second signal paths are transceiver paths; and
wherein the third signal path is a receive path.

12. The electrical multiband component of claim 2, wherein the first and second signal paths are each configured for transmission of mobile radio band signals; and
wherein the third signal path is configured for transmission of global positioning system (GPS) signals.

13. The electrical multiband component of claim 2, wherein the double mode SAW filter comprises an acoustic track comprising at least five transducers.

14. The electrical multiband component of claim 13, wherein the double mode SAW filter comprises:
input transducers in parallel; and
output transducers in parallel;
wherein an input transducer is between two of the output transducer; or
wherein an output transducer is between two of the input transducers.

15. The electrical multiband component of claim 2, wherein the bandpass filter comprises at least one first resonator upstream of the double mode SAW filter relative to the antenna Path.

16. The electrical multiband component of claim 15, wherein the bandpass filter comprises at least one second resonator downstream of the double mode SAW filter relative to the antenna path.

17. The electrical multiband component of claim 16, wherein at least one first resonator or second resonator comprises a series resonator.

18. The electrical multiband component of claim 16, wherein at least one first resonator or second resonator comprises a parallel resonator.

19. The electrical multiband component of claim 16, wherein at least one first resonator or second resonator comprises part of at least one ladder-type element.

20. The electrical multiband component of claim 1, wherein the bandpass filter has a symmetrical output.

21. The electrical multiband component of claim 5, wherein the second high-pass filter has a transfer function that has a pole at a frequency located essentially in the first frequency band or the third frequency band.

22. The electrical multiband component of claim 5, wherein the first signal path comprises a third low-pass filter.

23. The electrical multiband component of claim 22, wherein the third low-pass filter has a transfer function that has a pole at a frequency located essentially in the second frequency band or the third frequency band.

24. The electrical multiband component of claim 5, further comprising:
a first matching network downstream of the second low-pass filter relative to the antenna path.

25. The electrical multiband component of claim 24, further comprising:
a second matching network downstream of the bandpass filter relative to the antenna input.

26. The electrical multiband component of claim 2, wherein the second and third signal paths are receive paths and the first signal path is a transmit/receive path; or
wherein the first and third signal paths are receive paths and the second signal path is a transmit/receive path.

27. The electrical multiband component of claim 1,
wherein the frequency-separating filter comprises the bandpass filter and a diplexer; and
wherein the diplexer interfaces first and second signal paths to a common path that is connected to a third signal path and to an antenna path.

28. The electrical multiband component of claim 1, which is surface-mountable.

29. The electrical multiband component of claim 28, further comprising:
a carrier substrate;
wherein the bandpass filter comprises a chip that is mounted on the carrier substrate.

30. The electrical multiband component of claim 29, wherein the carrier substrate comprises metallization planes and ceramic layers among the metallization planes.

31. The electrical multiband component of claim 29, wherein the frequency-separating filter is integrated, at least in part, into the carrier substrate.

32. The electrical multiband component 27, wherein in at least one of the first and second signal paths comprises a duplexer.

33. The electrical multiband component of claim 32, wherein the duplexer is integrated, at least in part, on a carrier substrate on which the bandpass filter is mounted.

34. The electrical multiband component of claim 33, further comprising:
at least one amplifier mounted on the carrier substrate, the at least one amplifier being in at least one of the first and second signal paths.

35. The electrical multiband component of claim 34, further comprising:
an additional signal path that is electromagnetically coupled, via a directional coupler, to a transmission branch of the first signal path or the second signal path; and
wherein the directional coupler is integrated in the carrier substrate or is on the carrier substrate.

36. The electrical multiband component of claim 35, wherein the additional signal path is electromagnetically coupled to the transmission branch of the first signal path and to the transmission branch of the second signal path.
